(19) United States
(12) Patent Application Publication
(10) Pub. No.: US 2026/0113034 A1
(43) Pub. Date: Apr. 23, 2026

(54) BUFFER WITH IMPROVED SLEW RATE AND SOURCE DRIVER INCLUDING THE SAME

(71) Applicant: SAMSUNG ELECTRONICS CO., LTD., Suwon-si (KR)

(72) Inventors: Donghan LEE, Suwon-si (KR); Jejin LEE, Suwon-si (KR)

(73) Assignee: SAMSUNG ELECTRONICS CO., LTD., Suwon-si (KR)

(21) Appl. No.: 19/300,248

(22) Filed: Aug. 14, 2025

(30) Foreign Application Priority Data
Oct. 21, 2024 (KR) 10-2024-0144161

(51) Int. Cl. H03K 17/74; G09G 3/3275; H03K 17/687

(52) U.S. Cl. CPC H03K 17/74; G09G 3/3275; H03K 17/6871; G09G 2310/0291; G09G 2330/021

(57) ABSTRACT

A buffer circuit includes an operational amplifier and a slew boosting circuit. The operational amplifier amplifies a first input voltage of a first input node to generate an output voltage of an output node. The slew boosting circuit performs a slew boosting operation of adjusting a slew rate of the output voltage, based on a difference between a voltage level of the first input voltage and a voltage level of the output voltage. The slew boosting circuit includes a diode boosting circuit located between the first input node and a second input node and including at least one diode. The slew boosting circuit also includes a comparing circuit located between the second input node and the output node and comparing a voltage level of a second input voltage of the second input node and the voltage level of the output voltage.

### CROSS-REFERENCE TO RELATED APPLICATIONS

This application claims priority under 35 U.S.C. § 119 to Korean Patent Application No. 10-2024-0144161 filed on Oct. 21, 2024, in the Korean Intellectual Property Office, the disclosures of which are incorporated by reference herein in their entireties.

### BACKGROUND

Embodiments of the present disclosure described herein relate to a buffer circuit and a source driver including the same.

A display device, which is used in an electronic device displaying an image, such as a television (TV), a laptop computer, a monitor, or a mobile device, includes a liquid crystal device (LCD) or an organic light emitting device (OLED). In particular, because the liquid crystal display device is thinner and lighter than a cathode ray tube and the quality of the liquid crystal display device is being improved, the liquid crystal display device is being widely used as an information processing device.

The display device may include a display panel including a plurality of pixels and a display driver for applying electrical signals to the plurality of pixels, and an image may be implemented by the electrical signals that the display driver provides to the plurality of pixels. Recently, various studies have been conducted to improve the performance of the display device such as a resolution and a slew rate.

### SUMMARY

Embodiments of the present disclosure provide a buffer circuit with an improved slew rate by preventing a slew boosting operation from being terminated before a voltage level of an output voltage reaches a target voltage.

### BRIEF DESCRIPTION OF THE FIGURES

The above and other objects and features of the present disclosure will become apparent by describing in detail embodiments thereof with reference to the accompanying drawings.

FIG. 1 is a diagram illustrating a buffer circuit according to an embodiment of the present disclosure.

FIG. 2 is a diagram illustrating an example of a diode boosting circuit of a buffer circuit of FIG. 1.

FIG. 3A is a diagram illustrating a slew rate of a comparative example in which a diode boosting circuit is not provided.

FIG. 3B is a diagram illustrating a slew rate of a buffer circuit of FIG. 1, in which a diode boosting circuit is provided.

FIG. 4 is a diagram illustrating an example of a slew boosting circuit according to an embodiment of the present disclosure.

FIGS. 5A to 5E are diagrams describing an operation of a diode boosting circuit of FIG. 4.

FIG. 6 is a diagram illustrating an example of a slew boosting circuit according to an embodiment of the present disclosure.

FIGS. 7A to 7C are diagrams describing an operation of a diode boosting circuit of FIG. 6.

FIG. 8 is a diagram describing how a slew rate is improved depending on an operation of a diode boosting circuit of FIG. 6.

FIGS. 9 to 10B are diagrams illustrating an example of a slew boosting circuit according to an embodiment of the present disclosure.

FIG. 11 is a block diagram illustrating a source driver including a buffer circuit according to example embodiments of the present disclosure.

FIG. 12 is a block diagram of a display device according to example embodiments of the present disclosure.

FIG. 13 is a flowchart describing an operation of a buffer circuit according to an embodiment of the present disclosure.

### DETAILED DESCRIPTION

Below, embodiments of the present disclosure will be described in detail and clearly to such an extent that an ordinary one in the art easily carries out the present disclosure.

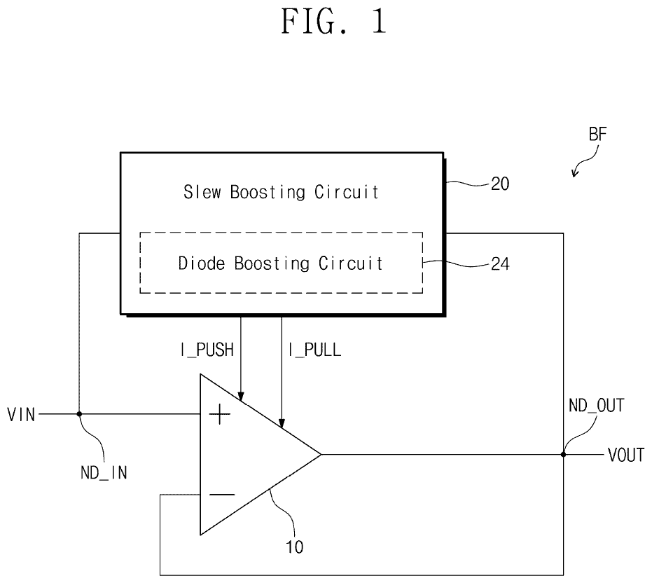

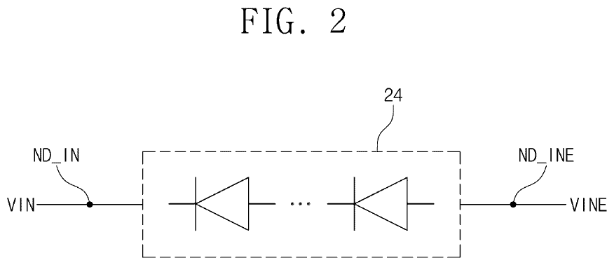

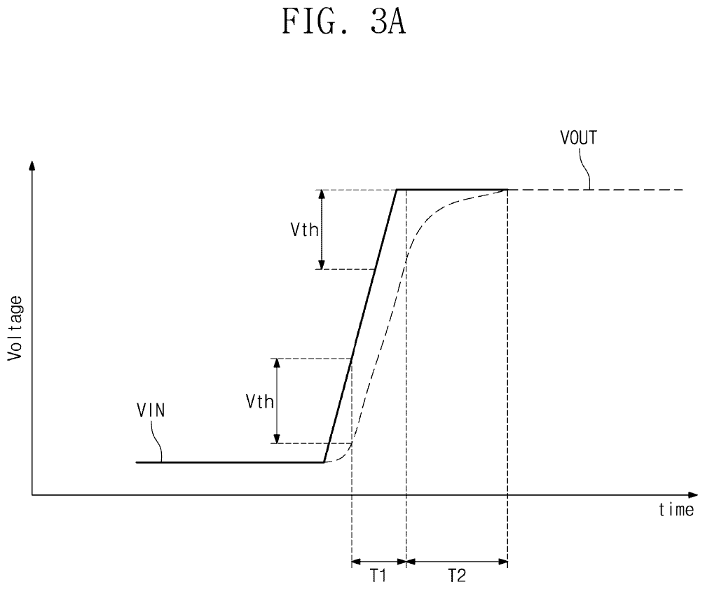

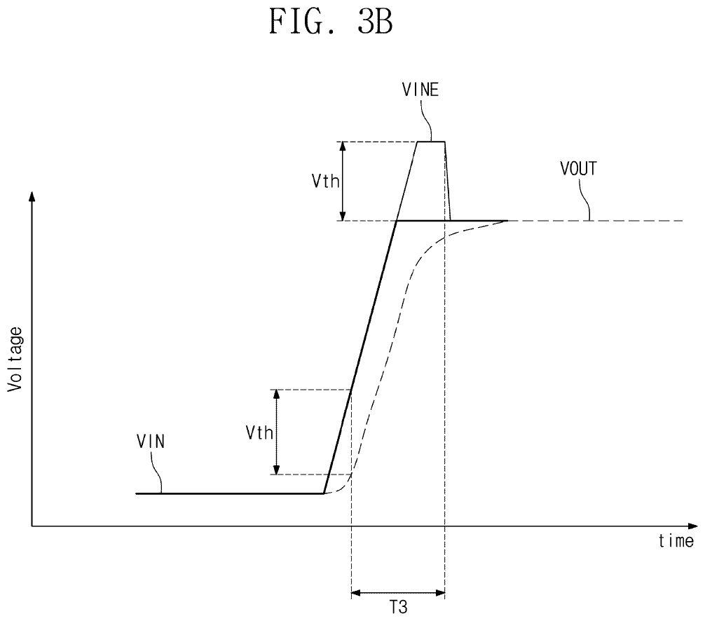

FIG. 1 is a diagram illustrating a buffer circuit according to an embodiment of the present disclosure, and FIG. 2 is a diagram illustrating an example of a diode boosting circuit of a buffer circuit of FIG. 1. FIG. 3A is a diagram illustrating a slew rate of a comparative example in which a diode boosting circuit is not provided, and FIG. 3B is a diagram illustrating a slew rate of a buffer circuit of FIG. 1, in which a diode boosting circuit is provided.

A buffer circuit BF according to an embodiment of the present disclosure may support a slew boosting operation and thus may provide an improved slew rate. In particular, the buffer circuit BF according to an embodiment of the present disclosure may divide an input node into a first input node and a second input node and may include a diode boosting circuit disposed between the first input node and the second input node and including at least one diode. In the slew boosting operation, the diode boosting circuit may increase or decrease the voltage level of the second input node. In this case, the slew boosting operation may be prevented from being terminated before the voltage level of an output voltage reaches a target voltage, and thus, the buffer circuit BF may provide a more improved slew rate.

Referring to FIG. 1, the buffer circuit BF may include an operational amplifier 10 and a slew boosting circuit 20.

The operational amplifier 10 may amplify the voltage level of an input voltage VIN to output an output voltage VOUT. The output voltage VOUT of the operational amplifier 10 may be input to a non-inverting input terminal of the operational amplifier 10 through a feedback loop. That is, the operational amplifier 10 may have a negative feedback structure in which the non-inverting input terminal and an output node ND_OUT are connected to each other. The operational amplifier 10 may have a rail-to-rail structure in which an input stage has a dual structure.

The slew boosting circuit 20 may generate a compensating current I_PUSH or I_PULL, based on a difference between the voltage level of the input voltage VIN and the voltage level of the output voltage VOUT. For example, when the difference between the voltage level of the input voltage VIN and the voltage level of the output voltage VOUT is greater than a reference voltage level, the slew boosting circuit 20 may generate the compensating current I_PUSH or I_PULL. For example, the reference voltage level may include the voltage level of the threshold voltage of an N-channel field effect transistor (NFET) or a P-channel field effect transistor (PFET) constituting the slew boosting circuit 20. The slew boosting circuit 20 may provide the compensating current I_PUSH or I_PULL to the operational amplifier 10.

In an embodiment, the case where a difference between the voltage level of the input voltage VIN at an input node ND_IN of the operational amplifier 10 and the voltage level of the output voltage VOUT at the output node ND_OUT of the operational amplifier 10 is greater than the reference voltage level and the magnitude of the input voltage VIN is greater than the magnitude of the output voltage VOUT may be expressed as “the input voltage VIN rises”. For example, when the input voltage VIN rises, the input voltage VIN may transition from a logical low level to a logical high level. In this case, the reference voltage level may be the threshold voltage level of the NFET or PFET described above.

When the input voltage VIN rises, the slew boosting circuit 20 may generate the pull compensating current I_PULL and may provide the pull compensating current I_PULL to the operational amplifier 10.

In this case, the operational amplifier 10 may quickly increase the voltage level of the output voltage VOUT based on the pull compensating current I_PULL. For example, the operational amplifier 10 may quickly increase the voltage level of the output voltage VOUT by turning off a transistor connected between a ground voltage and the output node ND_OUT based on the pull compensating current I_PULL. According to the above description, when the input voltage VIN rises, the slew rate may be improved.

In an embodiment, the case where the difference between the voltage level of the input voltage VIN at the input node ND_IN of the operational amplifier 10 and the voltage level of the output voltage VOUT at the output node ND_OUT of the operational amplifier 10 is greater than the reference voltage level and the magnitude of the input voltage VIN is smaller than the magnitude of the output voltage VOUT may be expressed as “the input voltage VIN falls”. For example, when the input voltage VIN falls, the input voltage VIN may transition from the logical high level to the logical low level.

When the input voltage VIN falls, the slew boosting circuit 20 may generate the push compensating current I_PUSH and may provide the push compensating current I_PUSH to the operational amplifier 10.

In this case, the operational amplifier 10 may quickly decrease the voltage level of the output voltage VOUT based on the push compensating current I_PUSH. For example, the operational amplifier 10 may quickly decrease the voltage level of the output voltage VOUT by turning off a transistor connected between a power supply voltage and the output node ND_OUT based on the push compensating current I_PUSH. According to the above description, when the input voltage VIN falls, the slew rate may be improved.

In the specification, the operation of improving the slew rate when the input voltage VIN rises may be referred to as a “rising slew boosting operation”. The operation of improving the slew rate when the input voltage VIN falls may be referred to as a “falling slew boosting operation”. Also, the slew boosting operation may indicate at least one of the rising slew boosting operation and/or the falling slew boosting operation.

In an embodiment of the present disclosure, the slew boosting circuit 20 may include a diode boosting circuit 24, and the diode boosting circuit 24 may be disposed between the first input node and the second input node. The diode boosting circuit 24 may include at least one diode. The diode boosting circuit 24 may prevent the slew boosting operation from being terminated before the voltage level of the output voltage VOUT reaches the target voltage, by increasing or decreasing the voltage level of the second input node.

In detail, in an embodiment, as illustrated in FIG. 2, the diode boosting circuit 24 may be disposed between the first input node ND_IN and a second input node ND_INE and may include at least one diode.

The first input node ND_IN connected to the diode boosting circuit 24 may correspond to the input node ND_IN of FIG. 1. That is, a voltage of the first input node ND_IN may correspond to the input voltage VIN. Below, the input voltage VIN may be referred to as a “first input voltage VIN”.

The second input node ND_INE connected to the diode boosting circuit 24 may be selectively connected to the first input node ND_IN. According to an embodiment, the second input node ND_INE may be referred to as an “edit input node”. A voltage of the second input node ND_INE may be referred to as a “second input voltage VINE”.

In an embodiment, when the slew boosting operation is not performed, the diode boosting circuit 24 may connect the second input node ND_INE directly to the first input node ND_IN. In this case, the second input voltage VINE of the second input node ND_INE may be the same as the first input voltage VIN of the first input node ND_IN.

In an embodiment, when the slew boosting operation is performed, the diode boosting circuit 24 may block the direct connection between the second input node ND_INE and the first input node ND_IN. That is, when a difference between the voltage level of the first and/or second input voltage VIN and/or VINE and the voltage level of the output voltage VOUT is greater than the reference voltage, the second input node ND_INE may be electrically connected to the first input node ND_IN through the at least one diode.

In this case, the voltage level of the second input voltage VINE of the second input node ND_INE may be different from the first input voltage VIN of the first input node ND_IN. For example, in the rising slew boosting operation, the voltage level of the second input voltage VINE of the second input node ND_INE may be higher than the voltage level of the first input voltage VIN of the first input node ND_IN. For example, in the slew boosting operation, the voltage level of the second input voltage VINE of the second input node ND_INE may be lower than the voltage level of the first input voltage VIN of the first input node ND_IN.

Accordingly, the buffer circuit BF according to an embodiment of the present disclosure may provide a more improved slew rate by making the voltage level of the second input voltage VINE of the second input node ND_INE different from the voltage level of the first input voltage VIN of the first input node ND_IN when the slew boosting operation is performed.

A rising slew boosting operation of a buffer circuit in which a diode boosting circuit is not provided is illustrated in FIG. 3A as an example. A rising slew boosting operation of a buffer circuit in which a diode boosting circuit according to an embodiment of the present disclosure is provided is illustrated in FIG. 3B as an example. For convenience of description, it is assumed that the reference voltage is a threshold voltage Vth of a sensing transistor.

Referring to FIG. 3A, the rising slew boosting operation is performed in a first time period T1 in which the difference between the voltage level of the input voltage VIN and the voltage level of the output voltage VOUT is greater than the voltage level of the reference voltage Vth. In this case, in a second time period T2, the difference between the voltage level of the input voltage VIN and the voltage level of the output voltage VOUT is smaller than the voltage level of the reference voltage Vth. Accordingly, before the voltage level of the output voltage VOUT reaches the target voltage, that is, in the second time period T2, the rising slew boosting operation is early terminated. That is, as the rising slew boosting operation is early terminated in the second time period T2, the effect of the rising slew boosting operation is limited.

In contrast, referring to FIG. 3B, during the execution of the rising slew boosting operation, through the diode boosting circuit 24, the buffer circuit BF according to an embodiment of the present disclosure may set the voltage level of the second input voltage VINE to be higher than the voltage level of the first input voltage VIN. For example, during a third time period T3, the difference between the voltage level during the second input voltage VINE and the voltage level of the output voltage VOUT may be set to be higher than the reference voltage Vth. In this case, the rising slew boosting operation may be continuously performed until the voltage level of the output voltage VOUT reaches the target voltage or almost reaches the target voltage.

As described above, the buffer circuit BF according to an embodiment of the present disclosure may include the diode boosting circuit 24 including at least one diode, and the diode boosting circuit 24 may be disposed between the first input node ND_IN and the second input node ND_INE. In the slew boosting operation, the buffer circuit BF may increase or decrease the voltage level of the second input node ND_INE by using the diode boosting circuit 24. In this case, the slew boosting operation may be prevented from being terminated before the voltage level of an output voltage reaches the target voltage, and thus, the buffer circuit BF may provide a more improved slew rate.

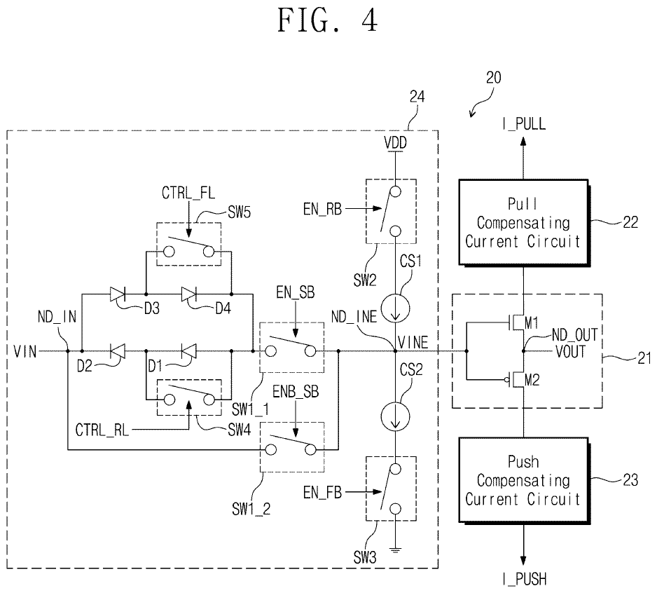

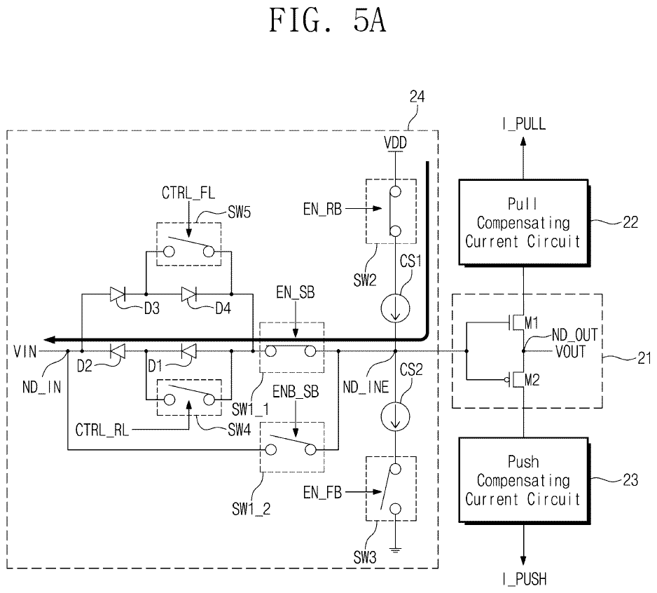

FIG. 4 is a diagram illustrating an example of a slew boosting circuit according to an embodiment of the present disclosure. A slew boosting circuit of FIG. 4 may correspond to the slew boosting circuit of FIG. 1.

Referring to FIG. 4, the slew boosting circuit 20 may include a comparing circuit 21, a pull compensating current circuit 22, a push compensating current circuit 23, and the diode boosting circuit 24.

The comparing circuit 21 may be selectively connected to the first input node ND_IN or the second input node ND_INE. For example, before entering the slew boosting operation mode, the comparing circuit 21 may be connected to the first input node ND_IN and may receive the first input voltage VIN. For example, after entering the slew boosting operation mode, the comparing circuit 21 may be connected to the second input node ND_INE and may receive the second input voltage VINE. Also, the comparing circuit 21 may be connected to the output node ND_OUT and may receive the output voltage VOUT.

The comparing circuit 21 may include transistors M1 and M2 each including a gate to which the first input voltage VIN or the second input voltage VINE is applied. The output voltage VOUT may be applied to a source terminal of the transistor M1 and a source terminal of the transistor M2. According to an embodiment, the transistors M1 and M2 of the comparing circuit 21 may be referred to as a “sensing transistor”.

The comparing circuit 21 may compare the voltage level of the first input voltage VIN and the voltage level of the output voltage VOUT and may generate a comparing current depending on a comparison result. That is, the comparing current may be a current corresponding to a difference between the voltage level of the first input voltage VIN and the voltage level of the output voltage VOUT.

When the difference between the voltage level of the input voltage VIN provided to the operational amplifier 10 (refer to FIG. 1) and the voltage level of the output voltage VOUT is greater than the reference voltage level and the magnitude of the input voltage VIN is greater than the magnitude of the output voltage VOUT, the first input voltage VIN may rise. For example, when the input voltage VIN rises, the input voltage VIN may transition from the logical low level to the logical high level. The reference voltage level may be the threshold voltage level of the transistor M1 or M2.

When the input voltage VIN rises, the comparing circuit 21 may be turned on the transistor M1 and may turn off the transistor M2. That is, the comparing circuit 21 may enable the pull compensating current circuit 22 and may disable the push compensating current circuit 23. As the pull compensating current circuit 22 is enabled, the rising slew boosting operation may be performed.

In the case of entering the rising slew boosting operation mode, the direct connection of the first input node ND_IN and the second input node ND_INE may be blocked, and the voltage level of the second input node ND_INE may be higher than the voltage level of the first input node ND_IN by the diode boosting circuit 24. That is, the second input voltage VINE higher than the first input voltage VIN may be provided to the gates of the comparing circuit 21. In this case, the rising slew boosting operation may be maintained until the voltage level of the output voltage VOUT reaches the target voltage or almost reaches the target voltage.

When the difference between the voltage level of the input voltage VIN provided to the operational amplifier 10 and the voltage level of the output voltage VOUT is greater than the reference voltage level and the magnitude of the input voltage VIN is smaller than the magnitude of the output voltage VOUT, the first input voltage VIN may fall. For example, when the input voltage VIN falls, the input voltage VIN may transition from the logical high level to the logical low level. The reference voltage level may be the threshold voltage level of the transistor M1 or M2.

When the input voltage VIN falls, the comparing circuit 21 may turn off the transistor M1 and may turn on the transistor M2. That is, the comparing circuit 21 may disable the pull compensating current circuit 22 and may enable the push compensating current circuit 23. As the push compensating current circuit 23 is enabled, the falling slew boosting operation may be performed.

In the case of entering the falling slew boosting operation mode, the direct connection of the first input node ND_IN and the second input node ND_INE may be blocked, and the voltage level of the second input node ND_INE may be lower than the voltage level of the first input node ND_IN by the diode boosting circuit 24. That is, the second input voltage VINE lower than the first input voltage VIN may be provided to the gates of the comparing circuit 21. In this case, the falling slew boosting operation may be maintained until the voltage level of the output voltage VOUT reaches the target voltage or almost reaches the target voltage.

The pull compensating current circuit 22 may be enabled when the transistor M1 is turned on and may generate the pull compensating current I_PULL provided to the operational amplifier 10. For example, the pull compensating current circuit 22 may include a plurality of transistors connected in the shape of a current mirror and may generate the pull compensating current I_PULL through a current mirror operation.

In this case, the operational amplifier 10 may quickly increase the voltage level of the output voltage VOUT based on the pull compensating current I_PULL. For example, the operational amplifier 10 may quickly increase the voltage level of the output voltage VOUT by turning off a transistor connected between the ground voltage and the output node ND_OUT based on the pull compensating current I_PULL.

According to an embodiment, the pull compensating current circuit 22 may be referred to as a “first boosting circuit”.

The push compensating current circuit 23 may be enabled when the transistor M2 is turned on and may generate the push compensating current I_PUSH provided to the operational amplifier 10. For example, the push compensating current circuit 23 may include a plurality of transistors connected in the shape of a current mirror and may generate the push compensating current I_PUSH through a current mirror operation.

In this case, the operational amplifier 10 may quickly decrease the voltage level of the output voltage VOUT based on the push compensating current I_PUSH. For example, the operational amplifier 10 may quickly decrease the voltage level of the output voltage VOUT by turning off a transistor connected between the power supply voltage and the output node ND_OUT based on the push compensating current I_PUSH.

According to an embodiment, the push compensating current circuit 23 may be referred to as a “second boosting circuit”.

The diode boosting circuit 24 may be connected to the gates of the transistors M1 and M2 of the comparing circuit 21. The diode boosting circuit 24 may be disposed between the first input node ND_IN and the second input node ND_INE and may include a plurality of diodes D1, D2, D3, and D4, a plurality of switches SW1_1, SW1_2, SW2, SW3, SW4, and SW5, and a plurality of current sources CS1 and CS2.

The plurality of diodes D1, D2, D3, and D4 may be disposed between the first input node ND_IN and the second input node ND_INE. At least one of the plurality of diodes D1, D2, D3, and D4 may be used to make the voltage level of the second input node ND_INE higher than the voltage level of the first input node ND_IN in the rising slew boosting operation.

For example, in the rising slew boosting operation, at least one of the first and second diodes D1 and D2 may be used to make the voltage level of the second input voltage VINE higher than the voltage level of the first input voltage VIN. As another example, in the falling slew boosting operation, at least one of the third and fourth diodes D3 and D4 may be used to make the voltage level of the second input voltage VINE lower than the voltage level of the first input voltage VIN.

The (1_1)-th switch SW1_1 may be turned on or turned off in response to a slew boosting enable signal EN_SB. The (1_2)-th switch SW1_2 may be turned on or turned off in response to a slew boosting disable signal ENB_SB.

For example, in the case of entering the rising slew boosting operation mode and/or the falling slew boosting operation mode, the (1_1)-th switch SW1_1 may be turned on in response to the slew boosting enable signal EN_SB, and the (1_2)-th switch SW1_2 may be turned off in response to the slew boosting disable signal ENB_SB. In this case, the first input node ND_IN and the second input node ND_INE may be connected to each other through at least one of the plurality of diodes D1, D2, D3, and D4.

For example, when the slew boosting operation is not performed, the (1_1)-th switch SW1_1 may be turned off in response to the slew boosting enable signal EN_SB, and the (1_2)-th switch SW1_2 may be turned on in response to the slew boosting disable signal ENB_SB. In this case, the first input node ND_IN and the second input node ND_INE may be directly connected to each other.

Herein, the slew boosting enable signal EN_SB and the slew boosting disable signal ENB_SB may be signals provided from the outside of the slew boosting circuit 20. However, this is provided as an example. According to an embodiment, the slew boosting enable signal EN_SB and the slew boosting disable signal ENB_SB may be generated within the slew boosting circuit 20.

The second switch SW2 may be turned on or turned off in response to a rising boosting enable signal EN_RB.

For example, in the case of entering the rising slew boosting operation mode, the second switch SW2 may be turned on in response to the rising boosting enable signal EN_RB, and thus, a current path may be formed in a first direction passing through at least one of the first and second diodes D1 and D2. In this case, the voltage level of the second input node ND_INE may be higher than the voltage level of the first input node ND_IN.

The third switch SW3 may be turned on or turned off in response to a falling boosting enable signal EN_FB.

For example, in the case of entering the falling slew boosting operation mode, the third switch SW3 may be turned on in response to the falling boosting enable signal EN_FB, and thus, a current path may be formed in a second direction passing through at least one of the third and fourth diodes D3 and D4. In this case, the voltage level of the second input node ND_INE may be lower than the voltage level of the first input node ND_IN.

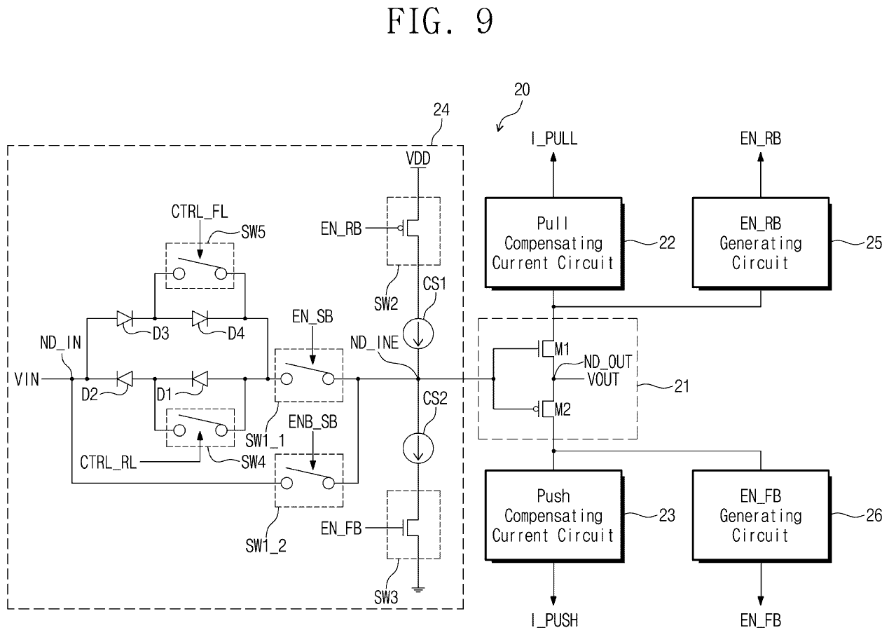

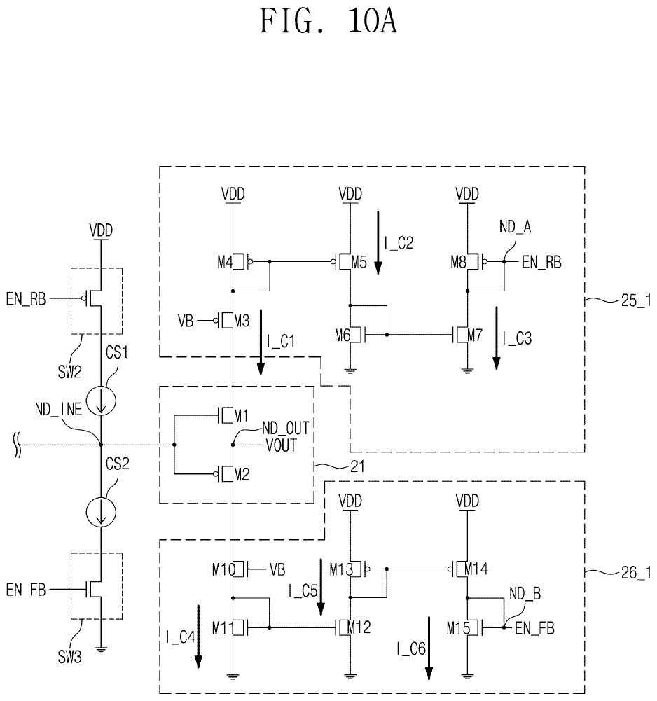

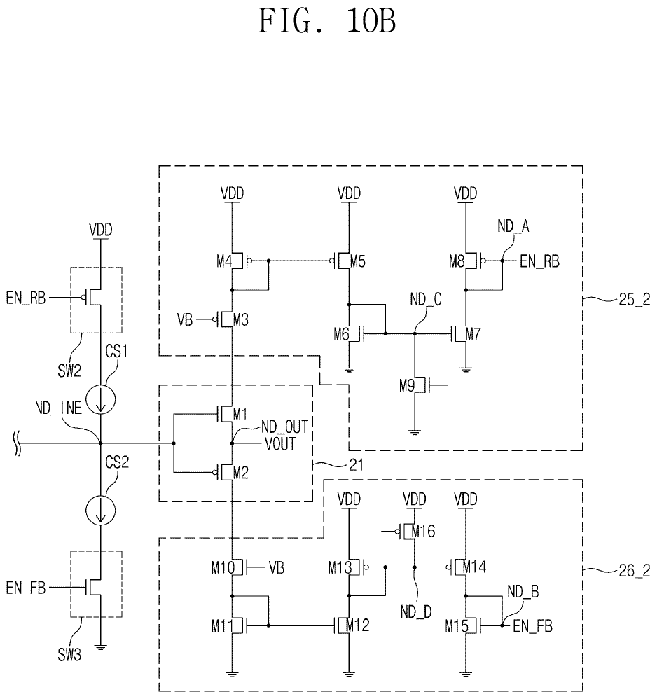

Herein, the rising boosting enable signal EN_RB and the falling boosting enable signal EN_FB may be signals generated within the slew boosting circuit 20. This will be described reference to FIGS. 9 to 10B. However, this is provided as an example. According to an embodiment, the rising boosting enable signal EN_RB and the falling boosting enable signal EN_FB may be generated from the outside of the slew boosting circuit 20.

The fourth switch SW4 may be turned on or turned off in response to a rising level control signal CTRL_RL. The fourth switch SW4 may be used to control the number of diodes through which the current path in the first direction passes in the rising slew boosting operation mode, such that the voltage level of the second input node ND_INE is controlled.

For example, the fourth switch SW4 may be turned on in response to the rising level control signal CTRL_RL. In this case, a first current path may pass through only the second diode D2 among the first and second diodes D1 and D2. As another example, the fourth switch SW4 may be turned off in response to the rising level control signal CTRL_RL. In this case, the first current path may pass through all the first and second diodes D1 and D2. The voltage level of the second input node ND_INE corresponding to the case where the current path is formed to pass through two diodes D1 and D2 may be relatively higher than the voltage level of the second input node ND_INE corresponding to the case where the current path is formed to pass through one diode D2.

The fifth switch SW5 may be turned on or turned off in response to a falling level control signal CTRL_FL. The fifth switch SW5 may be used to control the number of diodes through which a current path in a second direction passes in the falling slew boosting operation mode, such that the voltage level of the second input node ND_INE is controlled.

For example, the fifth switch SW5 may be turned on in response to the falling level control signal CTRL_FL. In this case, the second current path may pass through only the third diode D3 among the third and fourth diodes D3 and D4. As another example, the fifth switch SW5 may be turned off in response to the falling level control signal CTRL_FL. In this case, the second current path may pass through all the third and fourth diodes D3 and D4. The voltage level of the second input node ND_INE corresponding to the case where the current path is formed to pass through two diodes D3 and D4 may be relatively lower than the voltage level of the second input node ND_INE corresponding to the case where the current path is formed to pass through one diode D3.

A first current source CS1 may be disposed between the second switch SW2 and the second input node ND_INE. The first current source CS1 may be used to form the current path in the first direction in the rising slew boosting operation mode.

A second current source CS2 may be disposed between the third switch SW3 and the second input node ND_INE. The second current source CS2 may be used to form the current path in the second direction in the falling slew boosting operation mode.

Meanwhile, the description is given with reference to FIG. 4 as four diodes are provided. However, this is provided as an example, and the present disclosure is not limited thereto. The number of diodes may be variously changed and modified depending on the voltage level of the second input node ND_INE intended to be controlled. Also, according to an embodiment, at least one of the fourth and fifth switches SW4 and SW5 may be omitted.

Meanwhile, according to an embodiment, the diode boosting circuit 24 may be referred to as a “third boosting circuit”.

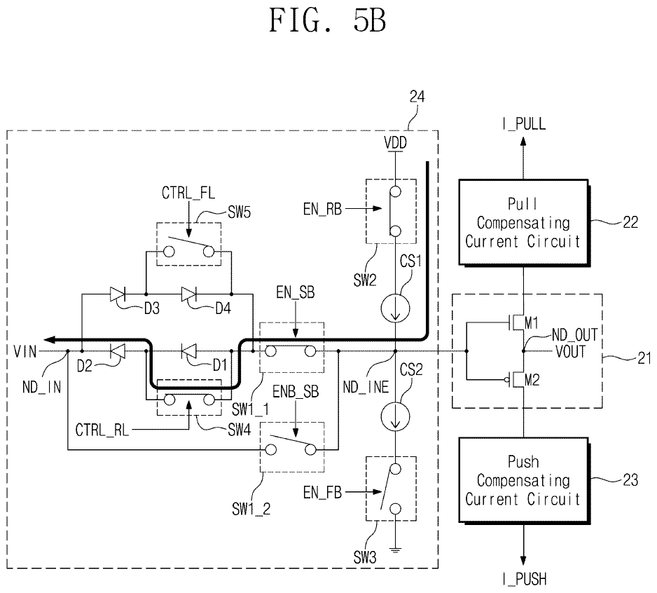

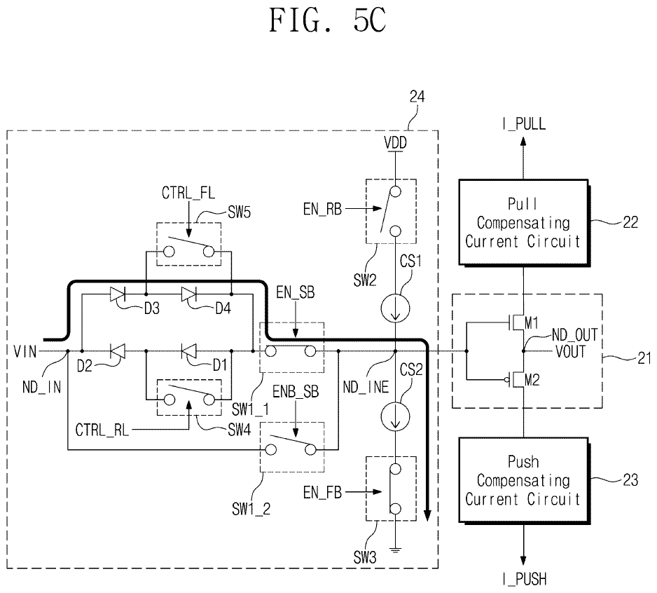

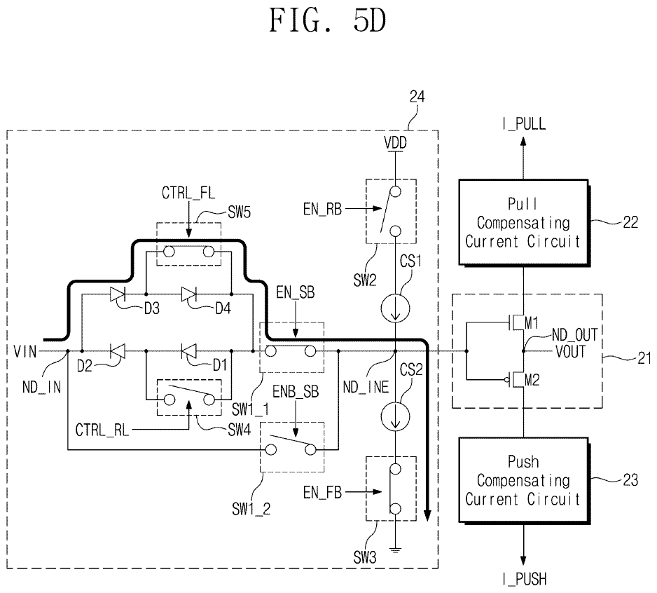

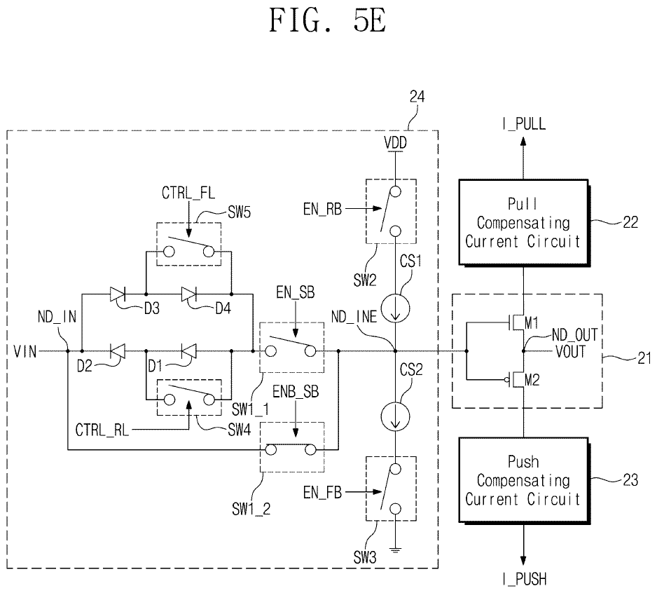

FIGS. 5A to 5E are diagrams for describing an operation of a diode boosting circuit of FIG. 4. Current paths that the diode boosting circuit generates in the rising slew boosting operation mode are illustrated in FIGS. 5A and 5B as an example. Current paths that the diode boosting circuit generates in the falling slew boosting operation mode are illustrated in FIGS. 5C and 5D as an example. The diode boosting circuit before entering the slew boosting operation mode is illustrated in FIG. 5E as an example.

Referring to FIG. 5A, in the rising slew boosting operation mode, the switches SW1_1 and SW2 may be turned on, and thus, the current path in the first direction may be formed. In this case, the fourth switch SW4 may be turned off. Accordingly, the current path in the first direction may pass through two diodes D1 and D2. As a result, the voltage level of the second input node ND_INE may be higher than the voltage level of the first input node ND_IN as much as a voltage level corresponding to two diodes. According to the above description, the rising slew boosting operation may be maintained until the voltage level of the output voltage VOUT reaches the target voltage or almost reaches the target voltage, and the slew rate may be improved increasingly.

Referring to FIG. 5B, in the rising slew boosting operation mode, the switches SW1_1 and SW2 may be turned on. In this case, the fourth switch SW4 may be turned on. Accordingly, the current path in the first direction may pass through one diode D2. As a result, the voltage level of the second input node ND_INE may be higher than the voltage level of the first input node ND_IN as much as a voltage level corresponding to one diode.

In this case, whether to turn on or turn off the fourth switch SW4 may be determined based on the threshold voltage of the transistor M1 of the comparing circuit 21.

Referring to FIG. 5C, in the falling slew boosting operation mode, the switches SW1_1 and SW3 may be turned on, and thus, the current path in the second direction may be formed. In this case, the fifth switch SW5 may be turned off. Accordingly, the current path in the second direction may pass through two diodes D3 and D4. As a result, the voltage level of the second input node ND_INE may be lower than the voltage level of the first input node ND_IN as much as a voltage level corresponding to two diodes. According to the above description, the falling slew boosting operation may be maintained until the voltage level of the output voltage VOUT reaches the target voltage or almost reaches the target voltage, and the slew rate may be improved increasingly.

Referring to FIG. 5D, in the falling slew boosting operation mode, the switches SW1_1 and SW3 may be turned on. In this case, the fifth switch SW5 may be turned on. Accordingly, the current path in the second direction may pass through one diode D3. As a result, the voltage level of the second input node ND_INE may be lower than the voltage level of the first input node ND_IN as much as a voltage level corresponding to one diode.

In this case, whether to turn on or turn off the fifth switch SW5 may be determined based on the threshold voltage of the transistor M2 of the comparing circuit 21.

Referring to FIG. 5E, before entering the slew boosting operation mode, the switch SW1_2 may be turned on. Accordingly, the first input node ND_IN and the second input node ND_INE may be directly connected, and the input voltage VIN of the operational amplifier 10 (refer to FIG. 1) may be provided to the comparing circuit 21.

As described above, the buffer circuit BF according to an embodiment of the present disclosure may include the diode boosting circuit 24 including at least one diode, and the diode boosting circuit 24 may be disposed between the first input node ND_IN and the second input node ND_INE. In the slew boosting operation, the buffer circuit BF may increase or decrease the voltage level of the second input node ND_INE by using the diode boosting circuit 24. In this case, the slew boosting operation may be prevented from being terminated before the voltage level of an output voltage reaches the target voltage, and thus, the buffer circuit BF may provide a more improved slew rate.

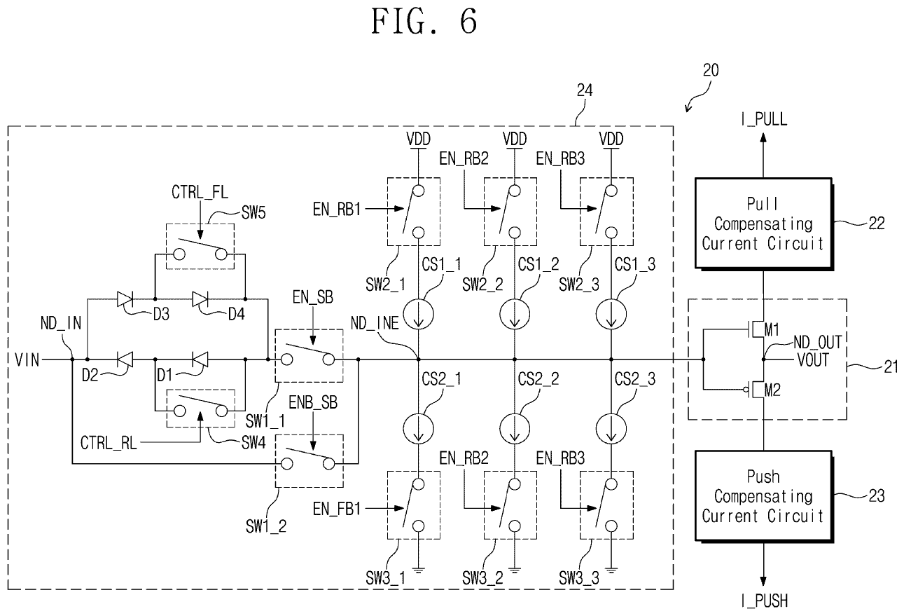

FIG. 6 is a diagram illustrating an example of a slew boosting circuit according to an embodiment of the present disclosure. A slew boosting circuit of FIG. 6 may correspond to the slew boosting circuit of FIGS. 1 and 4. Operations of the slew boosting circuit and the diode boosting circuit of FIG. 6 are similar to the operations of the slew boosting circuit and the diode boosting circuit described with reference to FIGS. 4 to 5E, and thus, additional description will be omitted to avoid redundancy.

Referring to FIG. 6, the diode boosting circuit 24 may further include a plurality of current sources CS1_1, CS1_2, and CS1_3 and a plurality of switches SW2_1, SW2_2, and SW2_3 used to generate a first current path in the rising slew boosting operation mode.

The plurality of switches SW2_1, SW2_2, and SW2_3 may be turned on or turned off in response to rising boosting enable signals EN_RB1, EN_RB2, and EN_RB3, respectively. That is, the plurality of switches SW2_1, SW2_2, and SW2_3 may be turned on or turned off independently of each other.

In this case, the intensity of the current in the first direction in the rising slew boosting operation mode may be determined depending on the number of switches turned on from among the plurality of switches SW2_1, SW2_2, and SW2_3.

In an embodiment, when a distance between a source driver including the buffer circuit BF (refer to FIG. 1) and a pixel is large, there is a need to set the intensity of the current in the first direction to a relatively high level. Herein, the case where the source driver and the pixel are distant from each other may be referred to as “FAR_END”. For example, under the “FAR_END” situation, the diode boosting circuit 24 may turn on three switches. According to the above description, a relatively high current may be generated in the rising slew boosting operation mode, and the slew rate may be effectively improved in the “FAR_END” situation.

In an embodiment, when a distance between a source driver including the buffer circuit BF and a pixel is small, there is a need to set the intensity of the current in the first direction to a relatively low level. Herein, the case where the source driver and the pixel are close to each other may be referred to as “NEAR_END”. For example, under the “NEAR_END” situation, the diode boosting circuit 24 may turn on one switch. According to the above description, a relatively low current may be generated in the rising slew boosting operation mode, and the slew rate may be effectively improved in the “NEAR_END” situation.

In an embodiment, when a distance between a source driver including the buffer circuit BF and a pixel is in a middle range (i.e., a source driver including the buffer circuit BF and a pixel are not distant from each other nor close to each other), there is a need to set the intensity of the current in the first direction to a medium level. Herein, the case where the distance between the source driver and the pixel is in a middle range may be referred to as “MID_END”. For example, under the “MID_END” situation, the diode boosting circuit 24 may turn on two switches. According to the above description, a current of a medium level may be generated in the rising slew boosting operation mode, and the slew rate may be effectively improved in the “MID_END” situation.

Continuing to refer to FIG. 6, the diode boosting circuit 24 may include a plurality of current sources CS2_1, CS2_2, and CS2_3 and a plurality of switches SW3_1, SW3_2, and SW3_3 used to generate a second current path in the falling slew boosting operation mode.

The plurality of switches SW3_1, SW3_2, and SW3_3 may be turned on or turned off in response to falling boosting enable signals EN_FB1, EN_FB2, and EN_FB3, respectively. That is, the plurality of switches SW3_1, SW3_2, and SW3_3 may be turned on or turned off independently of each other.

In this case, the intensity of the current in the second direction in the falling slew boosting operation mode may be determined depending on the number of switches turned on from among the plurality of switches SW3_1, SW3_2, and SW3_3.

In an embodiment, when a distance between a source driver including the buffer circuit BF and a pixel is large, there is a need to set the intensity of the current in the second direction to a relatively high level. In this case, the diode boosting circuit 24 may turn on three switches.

In an embodiment, when a distance between a source driver including the buffer circuit BF and a pixel is small, there is a need to set the intensity of the current in the second direction to a relatively low level. In this case, the diode boosting circuit 24 may turn on one switch.

In an embodiment, when a distance between a source driver including the buffer circuit BF and a pixel is in a middle range (i.e., a source driver including the buffer circuit BF and a pixel are not distant from each other nor close to each other), there is a need to set the intensity of the current in the second direction to a medium level. In this case, the diode boosting circuit 24 may turn on two switches.

As described above, the slew boosting circuit 20 according to an embodiment of the present disclosure may adjust the intensity of a current provided to the second input node ND_INE depending on a distance between a source driver including a buffer circuit and a pixel. Accordingly, the slew rate may be effectively improved.

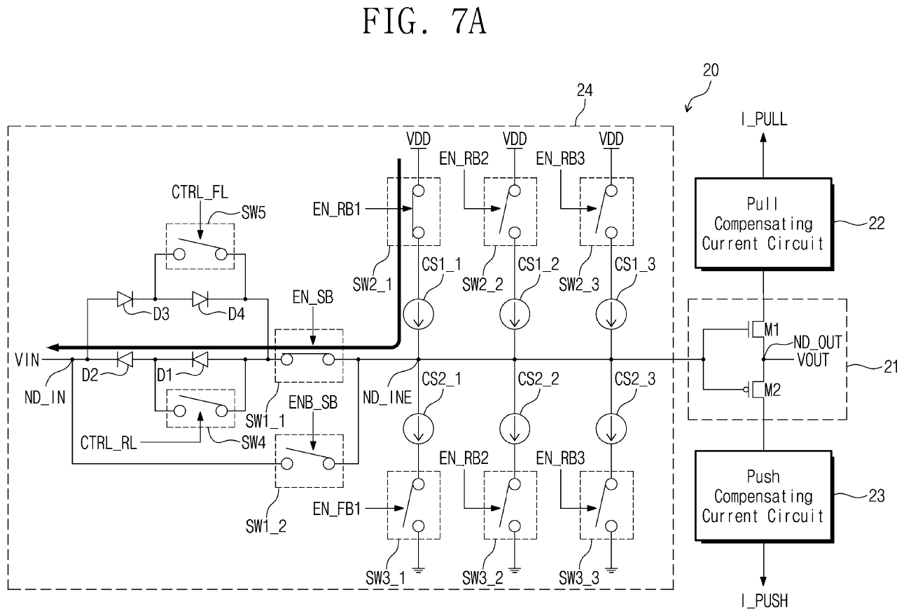

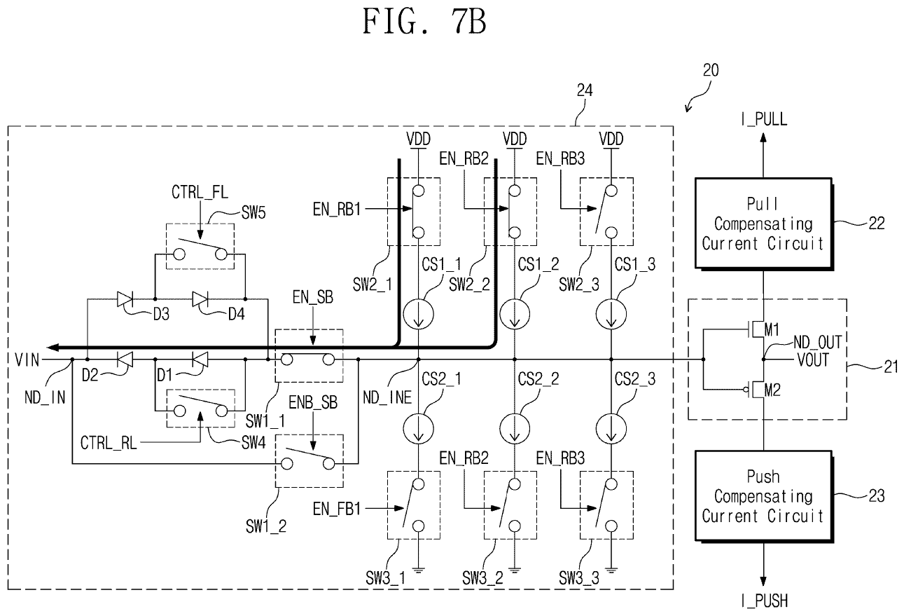

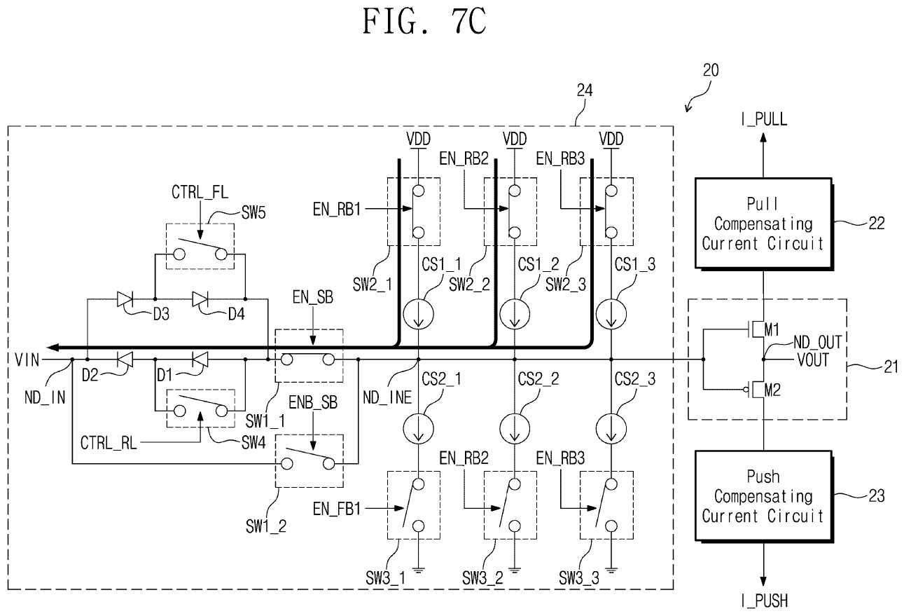

FIGS. 7A to 7C are diagrams for describing an operation of a diode boosting circuit of FIG. 6. An example of the rising slew boosting operation mode under the “NEAR_END” situation is illustrated in FIG. 7A. An example of the rising slew boosting operation mode under the “MID_END” situation is illustrated in FIG. 7B. An example of the rising slew boosting operation mode under the “FAR_END” situation is illustrated in FIG. 7C.

Referring to FIG. 7A, when the rising slew boosting operation is performed under the “NEAR_END” situation, only one switch SW2_1 among the plurality of switches SW2_1, SW2_2, and SW2_3 may be turned on. In this case, only one current source CS1_1 may be used to form the current path in the first direction, and thus, the intensity of a current flowing through the current path may be relatively low.

Referring to FIG. 7B, when the rising slew boosting operation is performed under the “MID_END” situation, two switches SW2_1 and SW2_2 among the plurality of switches SW2_1, SW2_2, and SW2_3 may be turned on. In this case, when two current sources CS1_1 and CS1_2 may be used to form the current path in the first direction, and thus, the intensity of a current flowing through the current path may be middle.

Referring to FIG. 7C, when the rising slew boosting operation is performed under the “FAR_END” situation, all the switches SW2_1, SW2_2, and SW2_3 may be turned on. In this case, when three current source CS1_1, CS1_2, and CS1_3 may be used to form the current path in the first direction, and thus, the intensity of a current flowing through the current path may be relatively high.

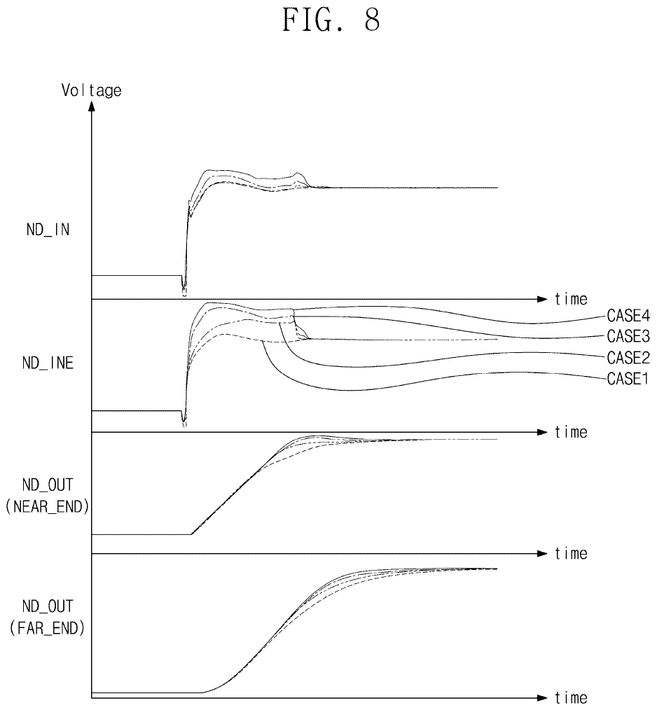

FIG. 8 is a diagram describing how a slew rate is improved depending on an operation of a diode boosting circuit of FIG. 6. Examples in which currents in the first direction, which have different intensities, are applied in the rising slew boosting operation mode are illustrated in FIG. 8.

Referring to FIG. 8, a first case CASE1 corresponds the case where the slew boosting circuit according to an embodiment of the present disclosure is not provided. A second case CASE2 corresponds to the case where the current path in the first direction is formed by using one current source, as illustrated in FIG. 7A. A third case CASE3 corresponds to the case where the current path in the first direction is formed by using two current sources, as illustrated in FIG. 7B. A fourth case CASE4 corresponds to the case where the current path in the first direction is formed by using three current sources, as illustrated in FIG. 7C.

As illustrated in FIG. 8, it is confirmed that the voltage level of the first input node ND_IN and the voltage level of the second input node ND_INE increase in order of the second case CASE2, the third case CASE3, and the fourth case CASE4.

Also, it is confirmed that the slew rate of the output node ND_OUT under the “NEAR_END” situation is relatively good in the second case CASE2. It is confirmed that the slew rate of the output node ND_OUT under the “FAR_END” situation is relatively good in the fourth case CASE4.

As described above, the slew boosting circuit 20 according to an embodiment of the present disclosure may adjust the intensity of a current provided to the second input node ND_INE depending on a distance between a source driver including a buffer circuit and a pixel. Accordingly, the slew rate may be effectively improved.

FIGS. 9 to 10B are diagrams illustrating an example of a slew boosting circuit according to an embodiment of the present disclosure. A slew boosting circuit of FIGS. 9 to 10B may correspond to the slew boosting circuit of FIGS. 1, 4, and 6. Operations of the slew boosting circuit and the diode boosting circuit of FIGS. 9 to 10B are similar to the operations of the slew boosting circuit and the diode boosting circuit described with reference to FIGS. 4 to 8, and thus, additional description will be omitted to avoid redundancy.

First, referring to FIG. 9, the slew boosting circuit 20 may internally generate the rising boosting enable signal EN_RB and the falling boosting enable signal EN_FB. To this end, the slew boosting circuit 20 may further include a first internal signal generating circuit 25 and a second internal signal generating circuit 26.

The first internal signal generating circuit 25 may generate the rising boosting enable signal EN_RB. For example, in the case of entering the rising slew boosting operation mode, the first internal signal generating circuit 25 may generate the rising boosting enable signal EN_RB based on a current mirror operation. To this end, the first internal signal generating circuit 25 may include a plurality of transistors constituting the current mirror.

In an embodiment, as illustrated in FIG. 10A, a first internal signal generating circuit 25_1 may include a plurality of transistors M3, M4, M5, M6, M7, and M8.

The third transistor M3 may be connected between the comparing circuit 21 and the fourth transistor M4. In the rising slew boosting operation, the third transistor M3 may be turned on in response to a bias voltage VB. However, this is provided as an example. According to an embodiment, the third transistor M3 may be omitted.

The fourth and fifth transistors M4 and M5 may be connected in the shape of a current mirror, and a power supply voltage VDD may be applied from one end. The fifth transistor M5 and the sixth distance M6 may be connected in series.

The sixth and seventh transistors M6 and M7 may be connected in the shape of a current mirror, and the power supply voltage VDD may be applied from one end.

The eighth transistor M8 and the seventh transistor M7 may be connected in series, and the power supply voltage VDD may be applied from one end. The gate and the drain of the eighth transistor M8 may be connected to each other.

When a difference between the voltage level of the first input node ND_IN and the voltage level of the output node ND_OUT is greater than the reference voltage and when the voltage level of the first input node ND_IN is greater than the voltage level of the output node ND_OUT, a first comparing current I_C1 may be generated. Also, each of second and third comparing currents I_C2 and I_C3 may be generated by the current mirror operation.

The eighth transistor M8 may be a transistor whose “W/L” value is relatively small. Herein, “W” may mean a width of a transistor, and “L” may mean a length of a transistor. In this case, because the gate-source voltage of the eighth transistor M8 has to be great for the generation of the third comparing current I_C3, the voltage level of a node ND_A decreases. As a result, in the case of entering the rising slew boosting operation mode, the rising boosting enable signal EN_RB of the logical low level may be generated; in this case, the rising boosting enable signal EN_RB may be provided to the second switch SW2 as an internal signal.

Returning to FIG. 9, the second internal signal generating circuit 26 may generate the falling boosting enable signal EN_FB. For example, in the case of entering the falling slew boosting operation mode, the second internal signal generating circuit 26 may generate the falling boosting enable signal EN_FB based on a current mirror operation. To this end, the second internal signal generating circuit 26 may include a plurality of transistors constituting the current mirror.

In an embodiment, as illustrated in FIG. 10A, a second internal signal generating circuit 26_1 may include a plurality of transistors M10, M11, M12, M13, M14, and M15.

The tenth transistor M10 may be connected between the comparing circuit 21 and the eleventh transistor M11. In the falling slew boosting operation, the tenth transistor M10 may be turned on in response to the bias voltage VB. However, this is provided as an example. According to an embodiment, the tenth transistor M10 may be omitted.

The eleventh and twelfth transistors M11 and M12 may be connected in the shape of a current mirror, and the ground voltage may be connected to one end. The twelfth transistor M12 and the thirteenth distance M13 may be connected in series.

The thirteenth and fourteenth transistors M13 and M14 may be connected in the shape of a current mirror, and the power supply voltage VDD may be applied from one end.

The fifteenth transistor M15 and the fourteenth transistor M14 may be connected in series, and one end may be connected to the ground voltage. The gate and the source of the fifteenth transistor M15 may be connected to each other.

When a difference between the voltage level of the first input node ND_IN and the voltage level of the output node ND_OUT is greater than the reference voltage and when the voltage level of the first input node ND_IN is smaller than the voltage level of the output node ND_OUT, a fourth comparing current I_C4 may be generated. Also, each of fifth and sixth comparing currents I_C5 and I_C6 may be generated by the current mirror operation.

The fifteenth transistor M15 may be a transistor whose “W/L” value is relatively small. Accordingly, the voltage level of a node ND_B may increase for the generation of the sixth comparing current I_C6. As a result, in the case of entering the falling slew boosting operation mode, the falling boosting enable signal EN_FB of the logical high level may be generated; in this case, the falling boosting enable signal EN_FB may be provided to the third switch SW3 as an internal signal.

Meanwhile, according to an embodiment, the first internal signal generating circuit 25 according to an embodiment of the present disclosure may further include an additional transistor such that the second switch SW2 is quickly turned off.

In an embodiment, as illustrated in FIG. 10B, a first internal signal generating circuit 25_2 may further include a ninth transistor M9 connected between a node ND_C and the ground voltage. When the rising slew boosting operation ends, the ninth transistor M9 may quickly discharge the node ND_C, and thus, the rising boosting enable signal EN_RB may quickly transition from the logical low level to the logical high level. As a result, the first internal signal generating circuit 25_2 may quickly turn off the second switch SW2.

Also, according to an embodiment, the first internal signal generating circuit 26 according to an embodiment of the present disclosure may further include an additional transistor such that the third switch SW3 is quickly turned off.

In an embodiment, as illustrated in FIG. 10B, a second internal signal generating circuit 26_2 may further include a sixteenth transistor M16 connected between a node ND_D and the power supply voltage VDD. When the falling slew boosting operation ends, the sixteenth transistor M16 may quickly charge the node ND_D, and thus, the falling boosting enable signal EN_FB may quickly transition from the logical high level to the logical low level. As a result, the second internal signal generating circuit 26_2 may quickly turn off the third switch SW3.

As described above, the slew boosting circuit 20 according to an embodiment of the present disclosure may internally generate the rising boosting enable signal EN_RB and the falling boosting enable signal EN_FB. This may mean that there is no need to include a separate line memory for storing information about a previous line and a current line of a pixel array. In addition, the slew boosting circuit 20 according to an embodiment of the present disclosure may prevent the slew boosting operation from being terminated before the voltage level of the output voltage reaches the target voltage. Accordingly, the improved slew rate may be provided.

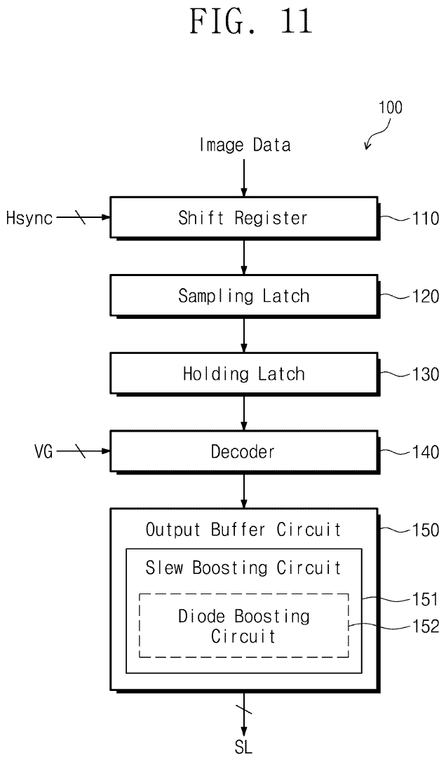

FIG. 11 is a block diagram illustrating a source driver including a buffer circuit according to example embodiments of the present disclosure.

Referring to FIG. 11, a source driver 100 may include a shift register 110, a sampling latch 120, a holding latch 130, a decoder 140, and an output buffer circuit 150. The output buffer circuit 150 may correspond to the buffer circuit BF described with reference to FIGS. 1 to 10.

The shift register 110 may control an operation timing of each of a plurality of sampling circuits included in the sampling latch 120 in response to a horizontal synchronization signal Hsync. The horizontal synchronization signal Hsync may be a signal with a given period.

The sampling latch 120 may sample image data depending on a shift order of the shift register 110. The image data that the sampling latch 120 samples may be stored in the holding latch 130.

The decoder 140 may include a digital-to-analog converter (DAC) and may receive a plurality of gamma voltages VG.

The decoder 140 may select at least one of the plurality of gamma voltages VG based on the image data stored in the holding latch 130. The number of gamma voltages VG may be determined depending on the number of bits of image data. For example, when image data are 8-bit data, the number of gamma voltages VG may be 256 or less, and when image data are 10-bit data, the number of gamma voltages VG may be 1024 or less.

The output buffer circuit 150 may include a plurality of output buffers implemented with an operational amplifier, and the plurality of output buffers may be connected to a plurality of source lines SL. Each of the plurality of output buffers may include a plurality of input terminals. The decoder 140 may select at least some of the gamma voltages VG based on the image data and may provide the selected voltage to the input terminals of each of the plurality of output buffers as an input voltage. Each of the plurality of output buffers may output the input voltage provided from the decoder 140 to a source line.

Each of the plurality of output buffers may include an operational amplifier, a slew boosting circuit 151, and a diode boosting circuit 152. The slew boosting circuit 151 may correspond to the slew boosting circuit described with reference to FIGS. 1 to 10, and the diode boosting circuit 152 may correspond to the diode boosting circuit described with reference to FIGS. 1 to 10. Accordingly, the slew boosting operation may be prevented from being terminated before the voltage level of the output voltage reaches the target voltage, and thus, the source driver 100 may provide an improved slew rate.

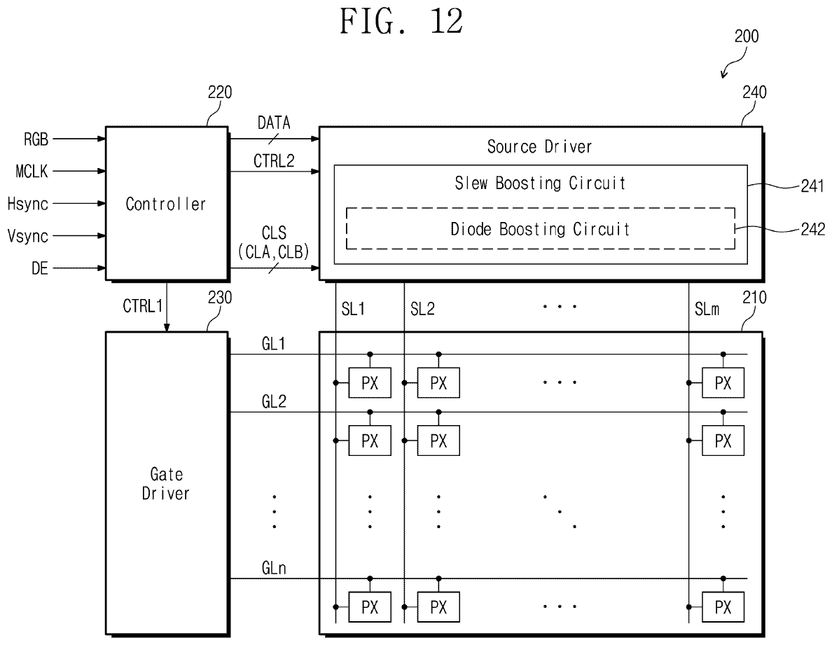

FIG. 12 is a block diagram of a display device according to example embodiments of the present disclosure. A display device 200 of FIG. 12 may include the buffer circuit and the source driver described with reference to FIGS. 1 to 11.

Referring to FIG. 12, the display device 200 may include a display panel 210, a controller 220, a gate driver 230, and a source driver 240.

The display panel 210 may include a plurality of pixels PX arranged in a matrix shape and may display an image in units of frame. The display panel 210 may be implemented with one of a liquid crystal display (LCD), a light emitting diode (LED) display, an organic LED (OLED) display, an active-matrix OLED (AMOLED) display, a micro LED display, an electrochromic display (ECD), a digital mirror device (DMD), an actuated mirror device (AMD), a grating light value (GLV), a plasma display panel (PDP), an electro luminescent display (ELD), a vacuum fluorescent display (VFD); besides, the display panel 210 may be implemented with any other kind of flat display or flexible display. Below, the OLED panel will be described as an example, but the present disclosure is not limited thereto.

The display panel 210 may include gate lines GL1 to GLn arranged in a column direction, source lines SL1 to SLm arranged in a row direction, and pixels PX formed at intersections of the gate lines GL1 to GLn and the source lines SL1 to SLm.

The pixels PX outputting a red (R) light, a green (G) light, and a blue (B) light may be repeatedly arranged in the display panel 210. For example, the pixels PX may be repeatedly arranged in order of R, G, and B or B, G, and R. Alternatively, the pixels PX the be repeatedly arranged in order of R, G, B, and G or B, G, R, and G.

Each of the pixels PX may include a light emitting diode and a driving circuit driving the light emitting diode independently. In detail, each pixel PX may include a diode driving circuit connected to a gate line and a source line and a light emitting diode connected between the diode driving circuit and the power supply voltage (or ground voltage).

The diode driving circuit may include a switching element, for example, a thin film transistor connected to the gate line. When the switching element is turned on by a gate on signal applied from the gate line, the diode driving circuit may supply an image signal received from the source line connected to the diode driving circuit to the light emitting diode. The diode may output a light signal corresponding to an image signal.

The controller 220 may receive a control signal from the outside. For example, the controller 220 may receive the horizontal synchronization signal Hsync, a vertical synchronization signal Vsync, a clock signal MCLK, a data enable signal DE, etc. from the outside. The controller 220 may generate control signals CTRL1, CTRL2, and CLS for controlling the gate driver 230 and the source driver 240 based on the received control signals. Various operation timings of the gate driver 230 and the source driver 240 may be controlled depending on the control signals CTRL1, CTRL2, and CLS.

Also, the controller 220 may receive image data RGB from the outside and may perform image processing for the received image data RGB or may convert the received image data RGB so as to be suitable for the structure of the display panel 210. The controller 220 may transmit the converted image data “DATA” to the source driver 240.

The gate driver 230 may supply the gate on signal sequentially to the gate lines GL1 to GLn in response to the gate control signal CTRL1 received from the controller 220. For example, the gate control signal CTRL1 may include a gate start pulse indicating an output start of the gate on signal, a gate shift clock controlling an output start of the gate on signal, etc. When the gate start pulse GSP is applied, in response to the gate shift clock GSC, the gate driver 230 may sequentially generate the gate on signal (e.g., a gate voltage of the logical low level) and may supply the gate on signal sequentially to the gate lines GL1 to GLn.

In this case, in a time period where the gate on signal is not supplied to the gate lines GL1 to GLn, a gate off signal (e.g., the gate voltage of the logical high level) may be supplied to the gate lines GL1 to GLn.

In response to the source control signal CTRL2 received from the controller 220, the source driver 240 may convert the image data “DATA” into image signals (e.g., a grayscale voltage corresponding to pixel data) and may output the image signals to a plurality of channels CH1 to CHk. For example, the source control signal CTRL2 may include a source start pulse, a source shift clock, a source output enable (SOE) signal, etc. The source driver 240 may include a plurality of driving units that provide an image signal of one horizontal line to the source lines SL1 to SLm during one horizontal period. Each driving unit may enable source lines connected to each driving unit.

The source driver 240 may include the source driver 100 described with reference to FIG. 11. In other words, an output buffer included in the source driver 240 may include a slew boosting circuit 241 and a diode boosting circuit 242. Accordingly, the slew boosting operation may be prevented from being terminated before the voltage level of the output voltage reaches the target voltage, and thus, the display device 200 may provide an improved slew rate.

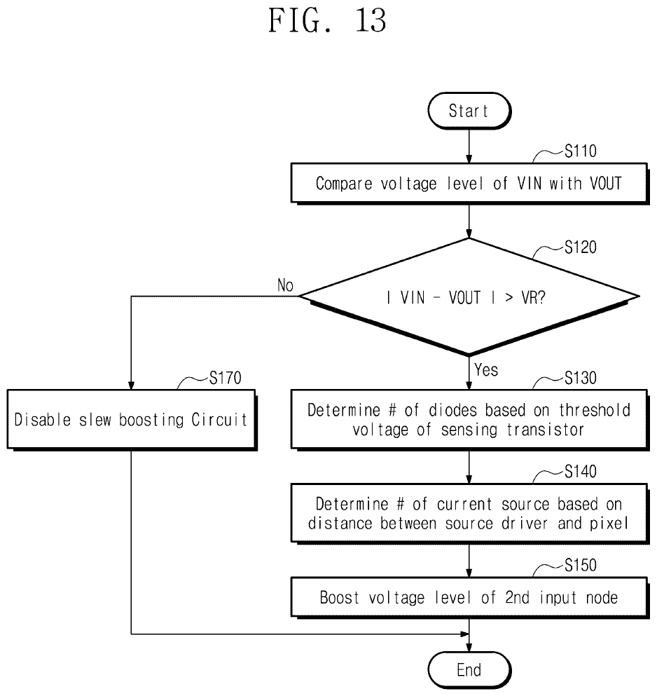

FIG. 13 is a flowchart for describing an operation of a buffer circuit according to an embodiment of the present disclosure. A buffer circuit of FIG. 13 may correspond to the buffer circuit described with reference to FIGS. 1 to 10.

In operation S110, the buffer circuit may compare the voltage level of the input voltage VIN and the voltage level of the output voltage VOUT.

In operation S120, the buffer circuit may determine whether a difference between the voltage level of the input voltage VIN and the voltage level of the output voltage VOUT is greater than a reference voltage VR. When the difference between the voltage level of the input voltage VIN and the voltage level of the output voltage VOUT is greater than the reference voltage VR, operation S130 may be performed.

In operation S130, the buffer circuit may determine the number of diodes to be located on a current path from among a plurality of diodes, based on a threshold voltage of a sensing transistor.

For example, as the magnitude of the threshold voltage of the sensing transistor becomes greater, the buffer circuit may increase the number of diodes to be located on the current path. As another example, as the magnitude of the threshold voltage of the sensing transistor becomes smaller, the buffer circuit may decrease the number of diodes to be located on the current path.

In operation S140, the buffer circuit may determine the intensity of current, based on a distance from the source driver to the pixel.

For example, when the distance from the source driver to the pixel is large, the buffer circuit may use relatively more current sources to form the current path. As another example, when the distance from the source driver to the pixel is small, the buffer circuit may use relatively less current sources to form the current path.

In operation S150, the buffer circuit may perform a boosting operation of increasing or decreasing the voltage level of the second input node, based on the number of diodes thus determined and the intensity of current.

For example, in the rising slew boosting operation mode, the buffer circuit may make the voltage level of the second input node higher than the voltage level of the first input node. As another example, in the falling slew boosting operation mode, the buffer circuit may make the voltage level of the second input node lower than the voltage level of the first input node.

According to the above description, the slew boosting operation may be maintained until the voltage level of the output voltage reaches the target voltage or almost reaches the target voltage. As a result, the slew rate may be improved.

Meanwhile, in operation S120, when the difference between the voltage level of the input voltage VIN and the voltage level of the output voltage VOUT is smaller than the reference voltage VR, operation S170 may be performed. In operation S170, the slew boosting circuit 20 may maintain a disabled state.

A buffer circuit according to an embodiment of the present disclosure may have an improved slew rate.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A buffer circuit comprising:
an operational amplifier configured to amplify a first input voltage of a first input node to generate an output voltage of an output node; and
a slew boosting circuit configured to perform a slew boosting operation of adjusting a slew rate of the output voltage, based on a difference between a voltage level of the first input voltage and a voltage level of the output voltage,
wherein the slew boosting circuit includes:
a diode boosting circuit located between the first input node and a second input node and including at least one diode; and
a comparing circuit located between the second input node and the output node, and configured to compare a voltage level of a second input voltage of the second input node and the voltage level of the output voltage, and
wherein, in the slew boosting operation, the voltage level of the second input voltage is boosted by the diode boosting circuit to be different from the voltage level of the first input voltage.

2. The buffer circuit of claim 1, wherein the diode boosting circuit includes:
a first diode;
a second diode located between the first input node and the first diode, wherein the first diode and the second diode are connected in series;
a first switch located between the first diode and the second input node, and configured to selectively connect the second input node to the first diode; and
a second switch located between the first input node and the second input node, and configured to selectively connect the first input node and the second input node.

3. The buffer circuit of claim 2, wherein the diode boosting circuit further includes:
a first current source connected to the second input node; and
a third switch located between the first current source and a power supply voltage.

4. The buffer circuit of claim 3, wherein, in a rising slew boosting operation mode, as the first switch and the third switch are turned on and the second switch is turned off, a current path passing through the first diode and the second diode in a direction from the second input node to the first input node is formed.

5. The buffer circuit of claim 3, wherein the diode boosting circuit further includes a fourth switch connected in parallel with the first diode, and
wherein, in a rising slew boosting operation mode, as the first switch, the third switch, and the fourth switch are turned on and the second switch is turned off, a current path passing through the second diode in a direction from the second input node to the first input node is formed.

6. The buffer circuit of claim 3, wherein the diode boosting circuit further includes:
a third diode connected to the first input node; and
a fourth diode located between the third diode and the first switch, wherein the third diode and the fourth diode are connected in series, and
wherein the first and second diodes are connected in parallel with the third and fourth diodes.

7. The buffer circuit of claim 6, wherein the diode boosting circuit further includes:
a second current source connected to the second input node; and
a fourth switch located between the second current source and a ground voltage.

8. The buffer circuit of claim 7, wherein, in a falling slew boosting operation mode, as the first switch and the fourth switch are turned on and the second switch is turned off, a current path passing through the third diode and the fourth diode in a direction from the first input node to the second input node is formed.

9. The buffer circuit of claim 7, wherein the diode boosting circuit further includes a fifth switch connected in parallel with the fourth diode, and
wherein, in a falling slew boosting operation mode, as the first switch, the fourth switch, and the fifth switch are turned on and the second switch is turned off, a current path passing through the third diode in a direction from the first input node to the second input node is formed.

10. The buffer circuit of claim 7, wherein the diode boosting circuit further includes:
a third current source connected to the second input node;
a fifth switch located between the second current source and the power supply voltage;
a fourth current source connected to the second input node; and
a sixth switch located between the third current source and the power supply voltage.

11. The buffer circuit of claim 10, wherein the diode boosting circuit determines the number of switches to be turned on from among the fourth switch, the fifth switch, and the sixth switch, based on a distance between the buffer circuit and a selected pixel.

12. The buffer circuit of claim 3, wherein the diode boosting circuit further includes:
a second current source connected to the second input node;
a fourth switch located between the second current source and the power supply voltage;
a third current source connected to the second input node; and
a fifth switch located between the third current source and the power supply voltage.

13. The buffer circuit of claim 12, wherein the diode boosting circuit determines the number of switches to be turned on from among the third switch, the fourth switch, and the fifth switch, based on a distance between the buffer circuit and a selected pixel.

14. The buffer circuit of claim 3, wherein the third switch operates in response to a rising boosting enable signal, and
wherein the diode boosting circuit further includes:
a first internal signal generating circuit configured to generate the rising boosting enable signal through a plurality of transistors constituting a current mirror.

15. The buffer circuit of claim 14, wherein the diode boosting circuit further includes:
a second current source connected to the second input node;
a fourth switch located between the second current source and a ground voltage, and configured to operate in response to a falling boosting enable signal; and
a second internal signal generating circuit configured to generate the falling boosting enable signal through a plurality of transistors constituting a current mirror.

16. A source driver comprising:
at least one buffer circuit,
wherein each of the at least one buffer circuit includes:
an operational amplifier configured to amplify a first input voltage of a first input node to generate an output voltage of an output node; and
a slew boosting circuit configured to perform a slew boosting operation of adjusting a slew rate of the output voltage, based on a difference between a voltage level of the first input voltage and a voltage level of the output voltage,
wherein the slew boosting circuit includes:
a diode boosting circuit located between the first input node and a second input node and including at least one diode; and
a comparing circuit located between the second input node and the output node, and configured to compare a voltage level of a second input voltage of the second input node and the voltage level of the output voltage, and
wherein, in the slew boosting operation, the voltage level of the second input voltage is boosted by the diode boosting circuit to be different from the voltage level of the first input voltage.

17. The source driver of claim 16, wherein the diode boosting circuit includes:
a first diode;
a second diode located between the first input node and the first diode, wherein the first diode and the second diode are connected in series;
a first switch located between the first diode and the second input node, and configured to selectively connect the second input node to the first diode;
a second switch located between the first input node and the second input node, and configured to selectively connect the first input node and the second input node;
a first current source connected to the second input node; and
a third switch located between the first current source and a power supply voltage.

18. The source driver of claim 17, wherein, in a rising slew boosting operation mode, as the first switch and the third switch are turned on and the second switch is turned off, a current path passing through the first diode and the second diode in a direction from the second input node to the first input node is formed.

19. The source driver of claim 17, wherein the diode boosting circuit further includes:
a third diode connected to the first input node;
a fourth diode located between the third diode and the first switch, wherein the third diode and the fourth diode are connected in series;
a second current source connected to the second input node; and
a fourth switch located between the second current source and a ground voltage.

20. A display device comprising:
a display panel including a plurality of pixels formed at intersections of gate lines arranged in a column direction and source lines arranged in a row direction;
a controller configured to generate a source control signal based on control signals received from an outside and to convert image data received from the outside; and
a source driver configured to convert the image data converted by the controller into an image signal in response to a source control signal received from the controller and to provide the image signal to the source lines,
wherein the source driver includes:
an operational amplifier configured to amplify a first input voltage of a first input node to generate an output voltage of an output node; and
a slew boosting circuit configured to perform a slew boosting operation of adjusting a slew rate of the output voltage, based on a difference between a voltage level of the first input voltage and a voltage level of the output voltage,
wherein the slew boosting circuit includes:
a diode boosting circuit located between the first input node and a second input node and including at least one diode; and
a comparing circuit located between the second input node and the output node, and configured to compare a voltage level of a second input voltage of the second input node and the voltage level of the output voltage, and
wherein, in the slew boosting operation, the voltage level of the second input voltage is boosted by the diode boosting circuit to be different from the voltage level of the first input voltage.
